(19) United States
(12) Patent Application Publication
(10) Pub. No.: US 2011/0317478 A1
(43) Pub. Date: Dec. 29, 2011

(54) Method and Circuit Arrangement for Performing a Write Through Operation, and SRAM Array With Write Through Capability

(75) Inventors: Yuen H. Chan, Poughkeepsie, NY (US); Michael Kugel, Boeblingen (DE); Antonio Pelella, Highland Falls, NY (US); Tobias Werner, Weil im Schoenicher (DE)

(73) Assignee: International Business Machines Corporation, Armonk, NY (US)

(21) Appl. No.: 13/150,458

(22) Filed: Jun. 1, 2011

(30) Foreign Application Priority Data
Jun. 25, 2010 (EP) 10167274.9

(51) Int. Cl. G11C 11/34; G11C 11/00

(52) U.S. Cl. 365/156; 365/154

(57) ABSTRACT

An improved method for performing a write through operation during a write operation of a SRAM cell (10) of a SRAM array (1) is disclosed. The method comprises suppressing a false write through data propagation at an output node (C, F) of the SRAM array (1) in case of a failure causing transition at a first node (t) or a second node (c) of the SRAM cell (10) by using information about the input data (data, data_b) to be written in the SRAM cell (10) and read data propagation paths to retain the output node (C, F) after a global bit line (gb_t, gb_c) at a precharge level independently from a logical level of the global bit line (gb_t, gb_c), if a corresponding node (c, t) of the SRAM cell (10) is performing the failure causing transition based on input data (data, data_b) to be written in the SRAM cell (10).

### BACKGROUND OF THE INVENTION

1. Field of the Invention

The present invention relates in general to the field of digital memory circuits, and in particular to a method for performing a write through operation, and a circuit arrangement for performing a write through operation. Still more particularly, the present invention relates to a Static Random Access Memory (SRAM) array with write through capability.

2. Description of the Related Art

Static random access memory (SRAM) is a type of volatile digital memory that retains data written to it so long as power is applied to the SRAM. One type of SRAM commonly used in high performance computational circuits is referred to as a “domino” SRAM. A domino SRAM can have write-though capability that allows a value being written into the SRAM to be read at the output of the SRAM in the same cycle that the value is being written. This feature is useful while performing memory and logic self tests.

When testing integrated circuits, techniques such as ABIST (Array Built In Self Test) and LBIST (Logic Built In Self Test) are used to test memory arrays (such as SRAM arrays) and logic elements. It is very important to be able to test the full latch to latch paths that are used in the chip function at the same frequency that will be used in the system application. If the circuits are tested at a slower frequency or part of the functional path is bypassed, then there could be delay defects that would not be caught by test but result in a failing chip when exercised in the system. This is a very expensive point to find and screen out failing parts.

A SRAM array typically includes SRAM cells with six or more transistors in which four transistors are configured as a cross-coupled latch for storing data. The remaining transistors are used as gating elements to obtain access to the SRAM cell. During a read access, different data stored in the memory cell is transferred to an attached bit line pair. A sense amplifier senses the differential voltage that develops across the bit line pair. During a write access, data is written into the memory cell through the differential bit line pair. Typically, one side of the bit line pair is driven to a logic low level potential and the other side is driven to a logic high level potential. The cells are arranged in an array that has a grid formed of bit lines and word lines, with the memory cells disposed at intersections of the bit lines and the word lines. The bit lines and the word lines are asserted or negated to enable at least one cell to be read or written to.

As will be appreciated by those skilled in the art, in prior art domino SRAM design the cells are arranged into groups of cells, typically on the order of eight to sixteen cells per group. Each cell in a group is connected to a local bit line pair. The local bit line pair for each group of cells is coupled to a global bit line pair. Rather than use sense amplifier to detect a differential voltage when reading a cell, in a domino SRAM the local bit lines are precharged and discharged by the cell in a read operation, which discharge is detected and determines the state of the cell. The local bit line, the precharge means, and the detection means define a dynamic node of the domino SRAM.

In a domino SRAM array, in the read operation the cell must be capable to discharge or retain the level of the local bit line without the help of a sense amplifier. In this situation, the “write” Operation becomes the primary design focus due to a situation called “Fast Read before Write”. In most cases, a new value being written to the SRAM cell will appear on the global bit line pair as it is being written to the SRAM cell, thus giving this circuit its “write-through” capability. In one case, referred to as an “early read” condition, where a “1” is being written to the SRAM cell to overwrite a “0” currently stored therein, a discharge of a corresponding global bit line occurs if the SRAM cell drives the local bit line with the “0” before the SRAM cell is flipped by the internal feedback loop. This discharge of the global bit line will be impossible to recover from until the next cycle, thereby resulting in an incorrect value being read on the global bit line during the “write-through” operation. This “False Write Through Propagation problem” cannot be suppressed with current implementations. Strong keeper devices at the local bit lines would help to avoid a “False Write Through propagation” but would also highly impact read and/or write performance.

In state of the art solutions cross coupled PFETs are suppressing false write through propagation in single read port designs, but this is not possible for supporting two independent read ports since independent bit lines are needed to employ independent read ports. If the real write trough is not needed, write bypass/around schemes may be used ignoring array output during write operations.

In the Patent Application Publication US 2009/0116324 A1 “APPARATUS FOR GUARANTEED WRITE THROUGH IN DOMINO READ SRAM'S” by Christensen et al. a digital device for facilitating recovery of a precharged dot line, periodically precharged by a precharge signal, that has been prematurely discharged as a result of an early read condition, is disclosed, wherein in the disclosed SRAM cells a single read/write port design is used. In the disclosed digital device a data input signal can have a selected one of a first value and a second value. The first value is a value that would be reflected by the dot line being in a charged state. A logic device that is responsive to the data input signal causes a charge to be applied to the dot line when the data signal has the first value.

In the U.S. Pat. No. 7,113,433 B2 “LOCAL BIT SELECT WITH SUPPRESSION OF FAST READ BEFORE WRITE” by Chan et al. a domino SRAM provided with active pull-up PFET devices that overwhelm “slow to write but very fast to read” cells is disclosed. The described pull-up PFET devices allow the cells to recover from timing mismatch situations. This approach allows the traditional “bit select” clamp to actively control the “local select” through “wired-or” PFET pull-up transistors. Separate read and write global “bit line” pairs allow the read and write performance to be optimized independently.

### SUMMARY OF THE INVENTION

The technical problem underlying the present invention is to provide a method for performing a write through operation and a circuit arrangement for performing a write through operation and a SRAM array with write through capability, which are able to solve false write through propagation problems and the above mentioned shortcomings and pain points of prior art write through operations.

According to the present invention this problem is solved by providing a method for performing a write through operation having the features of claim 1, a circuit arrangement for performing a write through operation having the features of claim 8, and a SRAM array with write through capability having the features of claim 14. Advantageous embodiments of the present invention are mentioned in the sub claims.

Accordingly, in an embodiment of the present invention a method for performing a write through operation during a write operation of a SRAM cell of a SRAM array, comprises suppressing a false write through data propagation at an output node of said SRAM array in case of a failure causing transition at a first node or a second node of the SRAM cell by using information about input data to be written in the SRAM cell and read data propagation paths to retain the output node after a global bit line at a precharge level independently from a logical level of the global bit line, if a corresponding node of the SRAM cell is performing the failure causing transition based on the input data to be written in the SRAM cell.

In further embodiments of the present invention the failure causing transition is a low-high-transition in case of a SRAM cell configured with NFETs as gating elements and the corresponding precharge level is a logical high level in case of a PFET used as precharge device, and wherein the failure causing transition is a high-low-transition in case of a SRAM cell configured with PFETs as gating elements and the corresponding precharge level is a logical low level in case of a NFET used as precharge device.

In further embodiments of the present invention, a first output node of the SRAM array after a true global bit line is forced to retain the precharge level, if a true node of the SRAM cell is performing the failure causing transition based on the input data, or a second output node of the SRAM array after a complementary global bit line is forced to retain the precharge level, if a complementary node of the SRAM cell is performing the failure causing transition based on the input data.

In further embodiments of the present invention, the input data is gated by a dynamic write enable signal to generate corresponding dynamic write data, wherein the input data and/or the dynamic write data are used to gain the information about the input data to be written in the SRAM cell.

In further embodiments of the present invention, the information about the input data to be written in the SRAM cell is represented by a failure causing transition of the input data and/or the dynamic write data.

In further embodiments of the present invention, the information about the input data is gated by a global clock signal to generate a corresponding false write through preventing signal.

In further embodiments of the present invention, the false write through preventing signal is used to control a precharge device to retain the corresponding output node at the precharge level and to control an evaluation device to prevent switching of the corresponding output node to the evaluation level.

In another embodiment of the present invention, a circuit arrangement for performing a write through operation during a write operation of a SRAM cell of a SRAM array, comprises false write through preventing means suppressing a false write through data propagation at an output node of said SRAM array in case of a failure causing transition at a first node or a second node of the SRAM cell by using information about input data to be written in the SRAM cell to generate a false write through preventing signal, which is used to retain the output node of a read data propagation path at a precharge level after a global bit line independently from a logical level of the global bit line, if a corresponding node of the SRAM cell is performing the failure causing transition based on the input data to be written in the SRAM cell.

In further embodiments of the present invention the failure causing transition is a low-high-transition in case of a SRAM cell configured with NFETs as gating elements and the corresponding precharge level is a logical high level in case of a PFET used as precharge device, and wherein the failure causing transition is a high-low-transition in case of a SRAM cell configured with PFETs as gating elements and the corresponding precharge level is a logical low level in case of a NFET used as precharge device.

In further embodiments of the present invention, a write data gating logic comprises at least one logical gate to gate the input data by a dynamic write enable signal to generate corresponding dynamic write data, wherein the input data and/or the dynamic write data are used to gain the information about the input data to be written in the SRAM cell.

In further embodiments of the present invention, the information about the input data to be written in said SRAM cell is represented by a failure causing transition of the input data and/or the dynamic write data.

In further embodiments of the present invention, the false write through preventing means comprises a logical gate to logically link the information about the input data to be written in the SRAM cell with a global clock signal to generate the corresponding false write through preventing signal.

In further embodiments of the present invention, the false write through preventing signal controls a precharge device in a connecting structure to retain the corresponding output node at the precharge level and an evaluation device in the false write through preventing means to prevent switching of the corresponding output node to the evaluation level.

In another embodiment of the present invention, a SRAM array with write through capability comprises a plurality of SRAM cells and corresponding local evaluation circuits with local bit lines and word lines for performing write and read operations, read head circuits to read logical level of global bit lines, a connecting structure to connect at least one SRAM subarray to a common output node, and a above described circuit arrangement for performing a write through operation during a write operation of a SRAM cell of the SRAM array, according to an embodiment of the present invention.

In further embodiments of the present invention, a dual bit line/dual word line approach is used and one write or two read port operations are performed per cycle.

All in all, embodiments of the present invention address the false write through propagation problem of a SRAM cell with write-through capability. The core idea of the present invention is to implement a method and/or a circuit arrangement for performing a write through operation during a write operation of a SRAM cell in high performance/low power SRAM arrays using a dual local bit line/dual local word line approach and providing one write or two read port operation per cycle. The primary focus of this invention is to provide a method and/or a circuitry for preventing false write through data from propagating to the array outputs during a write operation. In opposite to state of the art write bypass or write around schemes this invention uses the read data propagation paths to provide write through functionality in order to improve observability and testability of the circuit. By using the read data propagation paths it is advantageously possible to test the full latch to latch paths that are used in the chip function at the same frequency that will be used in the system application. So the efficiency in finding and screening out failing parts is advantageously increased.

Embodiments of the present invention employ an area efficient false write through blocking circuitry for SRAM designs without global bit select functionality by write data controlled blocking of false write through data right after global bit lines and avoiding usage of state of the art write bypass/write around schemes.

The above, as well as additional purposes, features, and advantages of the present invention will become apparent in the following detailed written description.

### BRIEF DESCRIPTION OF THE DRAWINGS

A preferred embodiment of the present invention, as described in detail below, is shown in the drawings, in which

FIG. 1 is a schematic block diagram of a SRAM array, in accordance with an embodiment of the present invention;

FIG. 2 is a schematic circuit diagram of an upper part of the SRAM array shown in FIG. 1, in accordance with an embodiment of the present invention; and

FIGS. 3 and 4 are diagrams showing waveforms at different nodes and/or on different lines of the SRAM array shown in FIGS. 1 and 2, wherein FIG. 4 shows a certain time period between t1 and t2 of FIG. 3 in greater detail.

### DETAILED DESCRIPTION OF THE PREFERRED EMBODIMENTS

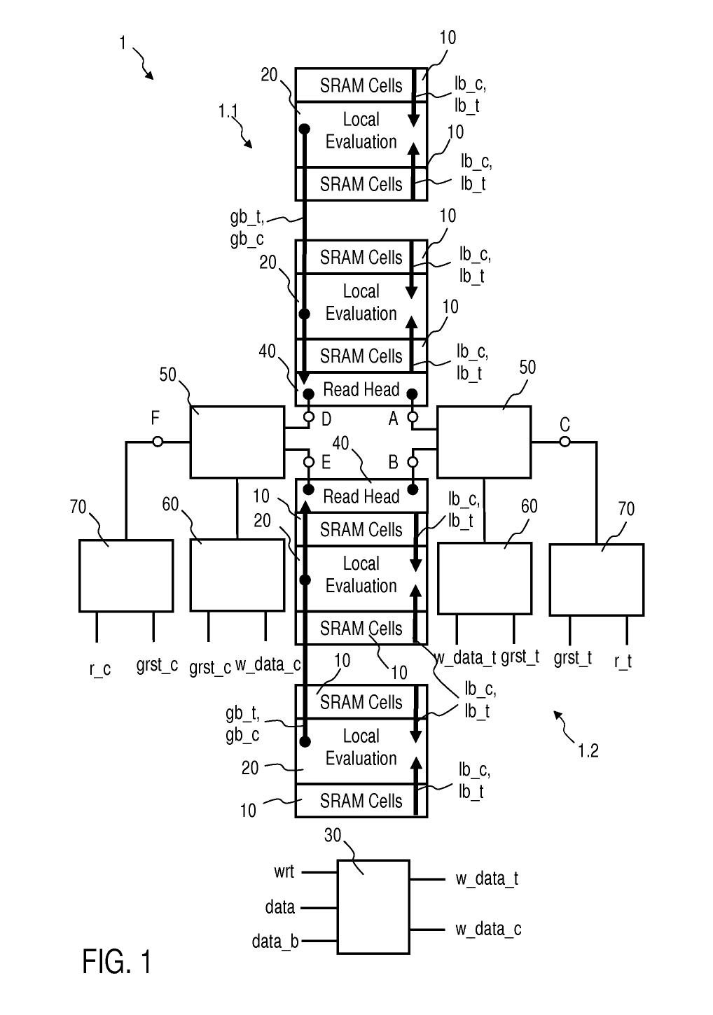

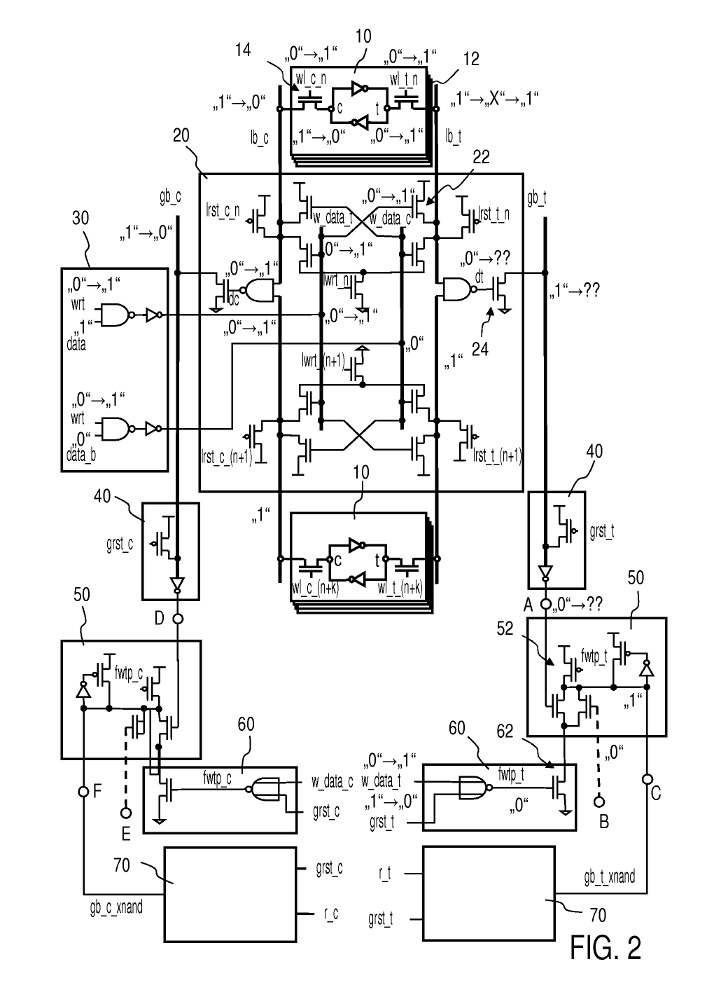

FIG. 1 is a schematic block diagram of a SRAM array 1 with write through capability, in accordance with an embodiment of the present invention, and FIG. 2 is a schematic circuit diagram of an upper part of the SRAM array 1 shown in FIG. 1, in accordance with an embodiment of the present invention. For the sake of simplicity, only the upper part of the SRAM array 1 is shown in detail herein.

Referring to FIGS. 1 and 2, the shown embodiment of the present invention employs a SRAM array 1 with write through capability comprising a plurality of SRAM cells 10 and corresponding local evaluation circuits 20 with local bit lines lb_t, lb_c and word lines wl_c_n, wl_t_n, wl_c_(n+k), wl_t_(n+k) for performing write and read operations, a write data gating logic 30 for generating dynamic write data w_data_t, w_data_c by combining input data data, data_b with a dynamic write enable signal wrt, read head circuits 40 to read logical level of global bit lines gb_t, gb_c, and a connecting structure 50 to connect at least one SRAM subarray 1.1, 1.2 to a common output node C, F.

In the shown embodiment the SRAM array 1 comprises a first SRAM subarray 1.1 in the upper part of FIG. 1 and a second SRAM subarray 1.2 in the lower part of FIG. 1. Further a first connecting structure 50 on the right side of FIGS. 1 and 2 connects a first circuit node A representing an inverted logical level of a true global bit line gb_t of the first subarray 1.1 and/or a second circuit node B representing an inverted logical level of a true global bit line gb_t of the second subarray 1.2 with the first output node C of the SRAM array 1 followed by a corresponding latch structure 70 using the logical signal gb_t_xnand and a true global clock signal grst_t to generate true read data r_t. A second connecting structure 50 on the left side of FIGS. 1 and 2 connects a third circuit node D representing an inverted logical level of a complementary global bit line gb_c of the first subarray 1.1 and/or a fourth circuit node E representing an inverted logical level of a complementary global bit line gb_c of the second subarray 1.2 with the second output node F of the SRAM array 1 followed by a corresponding latch structure 70 using the logical signal gb_c_xnand and a complementary global clock signal grst_c to generate complementary read data r_c.

The typical domino read SRAM array 1 shown in FIGS. 1 and 2 includes a plurality of SRAM cells 10 that are each accessed by asserting corresponding word lines wl_c_n, wl_t_n, wl_c_(n+k), wl_t_(n+k), wherein each shown block of SRAM cells 10 is representing a certain number of SRAM cells 10 connected to the same local bit line pair lb_t, lb_c. Each of the SRAM cells 10 includes a pair of cross-coupled inverters that maintain a current state between at least one pair of passgates 12, 14 that are allowed to conduct if the corresponding word lines wl_c_n, wl_t_n are asserted. Asserting the word lines wl_c_n, wl_t_n, wl_c_(n+k), wl_t_(n+k) allows the inverters to accept a new data value from a write line pair (referred to as w_data_t, w_data_c) and to put its dynamic write data w_data_t, w_data_c on the local bit line pair lb_t, lb_c.

The local evaluation circuits 20 are used to condition the dynamic write data w_data_t, w_data_c being written to the SRAM cell 10 and the read data read from the SRAM cell 10 by using different local restore lines lrst_t_n, lrst_t_(n+1), lrst_c_n, lrst_c_(n+1) and/or local write enable lines lwrt_n, lwrt_(n+1). The local evaluation circuits 20 include a top half and a bottom half, which are reflected copies of each other. Each half includes circuitry used to precharge the local bit line pair lb_t, lb_c used to write to or read from die SRAM cell 10. The local restore lines lrst_t_n, lrst_t_(n+1), lrst_c_n, lrst_c_(n+1) use PFETs to couple or decouple the local bit line pair lb_t, lb_c to a voltage source to be precharged when not being accessed. The local write enable lines lwrt_n, lwrt_(n+1) use NFETs to activate the top half or the bottom half of the corresponding local evaluation circuit 20.

According to the present invention a circuit arrangement comprising a false write through preventing means 60 is used to suppress a false write through data propagation at a corresponding output node C, F of the SRAM array 1 in case of a low-high-transition at a first node t or a second node c of a corresponding SRAM cell 10 by using information about input data data, data_b to be written in the SRAM cell 10 to generate a false write through preventing signal fwtp_t, fwtp_c, which is used to retain a corresponding output node C, F of a read data propagation path at a logical high level after a corresponding global bit line gb_t, gb_c independently from a logical level of the global bit line gb_t, gb_c, if a corresponding node c, t of the SRAM cell 10 is performing the low-high-transition based on input data data, data_b to be written in the SRAM cell 10. In the shown embodiment a first false write through preventing means 60 on the right side of the FIGS. 1 and 2 is used to suppress a false write through data propagation at the first output node C of the SRAM array 1, and a second false write through preventing means 60 on the left side of the FIGS. 1 and 2 is used to suppress a false write through data propagation at the second output node F of the SRAM array 1

Referring to FIG. 2 the write data gating logic 30 comprises at least one logical gate to gate the input data data, data_b by a dynamic write enable signal wrt to generate corresponding dynamic write data w_data_t, w_data_c, wherein the input data data, data_b and/or the dynamic write data w_data_t, w_data_c are used to gain the information about the input data data, data_b to be written in the SRAM cell 10. In the shown embodiment the information about the input data data, data_b to be written in the SRAM cell 10 is represented by a low-high-transition of the dynamic data w_data_t, w_data_c.

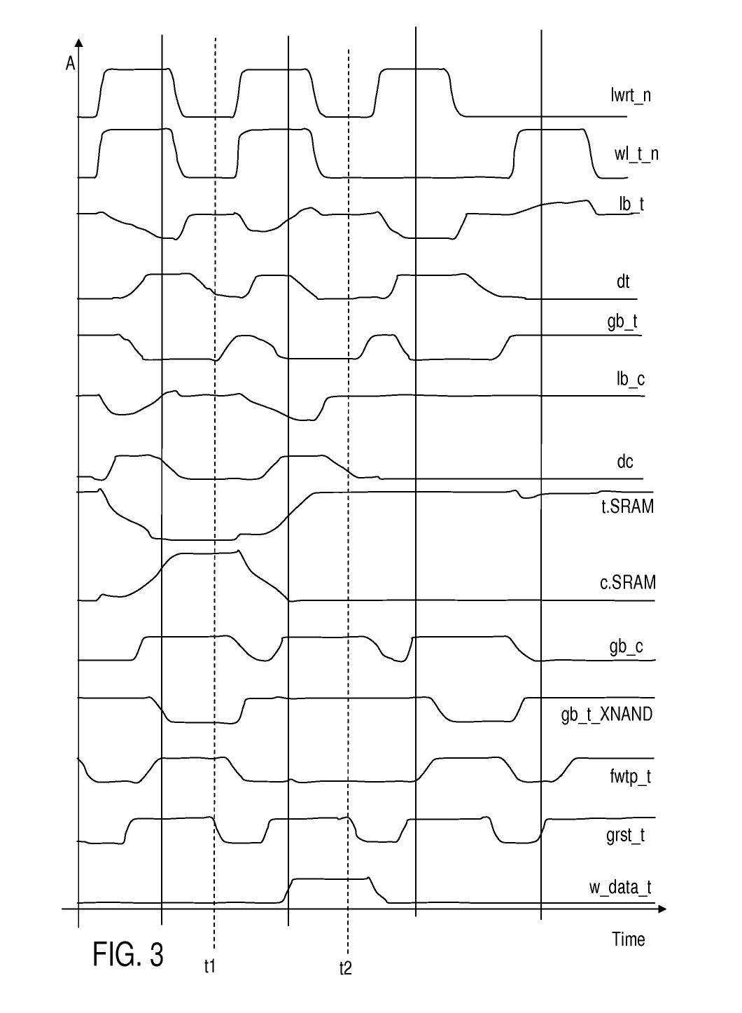

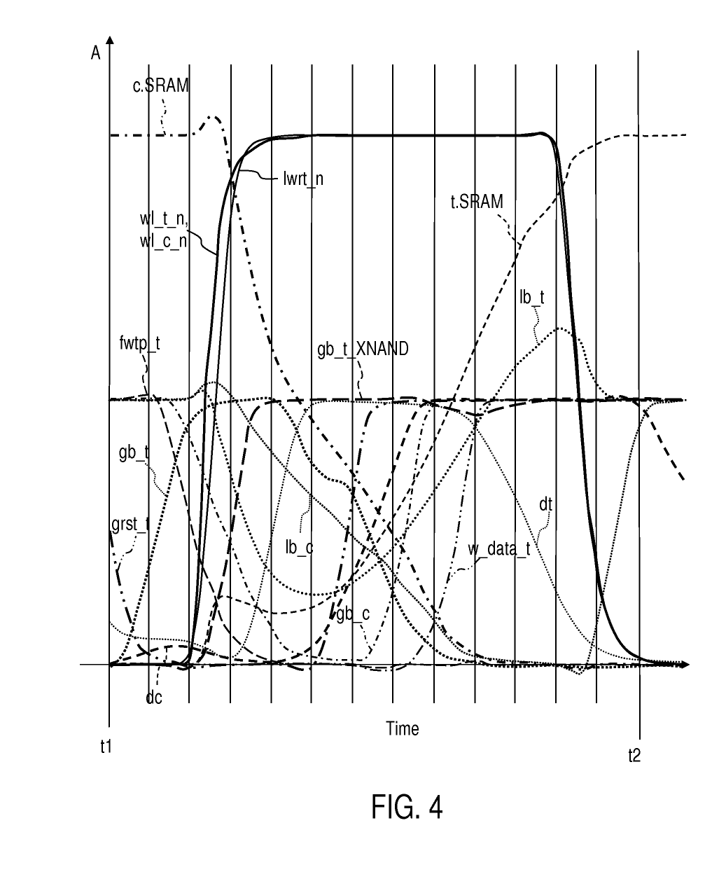

FIGS. 3 and 4 are showing waveforms lwrt_n, wl_t_n, lb_t, dt, gb_t, lb_c, dc, t.SRAM, c.SRAM, gb_c, gb_t XNAND, fwtp_t, grst_t, w_data_t at different nodes and/or on different lines of the SRAM array shown in FIGS. 1 and 2, wherein FIG. 4 shows a certain time period between t1 and t2 of FIG. 3 in greater detail.

Referring to FIGS. 2 to 4 a write operation with a corresponding write trough operation is described in the following. In most cases, a new value being written to the SRAM 10 will appear on the global bit line pair gb_t, gb_c as it is being written to the SRAM 10, thus giving this circuit its “write-through” capability. In one case, referred to as an “early read” condition, where a logical high level (“1”) is being written to the SRAM 10 to overwrite a logical low level (“0”) currently stored therein, the “0” driven by the SRAM 10 on a corresponding local bit line lb_t, lb_cb may cause a false write through propagation to the corresponding output node C, F.

For the sake of simplicity, only the case of a low-high-transition at the first node t of the SRAM cell 10 in the upper part of FIG. 2 during a write operation is described in the following, wherein a low-high-transition of the true dynamic data w_data_t is used as information to generate the false write through preventing signal fwtp_t in the first false write through preventing means 60 on the right side of FIG. 2. During the write operation, the word lines wl_c_n, wl_t_n, are raised from a low logical level to a high logical level, thereby coupling the first node t of the SRAM cell 10 to the true local bit line lb_t and the second node c of the SRAM cell 10 to the complementary local bit line lb_c. So the read operation of the write through operation may be started before the SRAM cell 10 is being flipped by the internal feedback loop, and the logical low level at the first node, which is to be changed to a logical high level due to the true dynamic write data w_data_t changing its level from the low logical level to the high logical level, may cause a discharge of the corresponding true local bit line lb_t. Since the NFET-Passgate 12 is weak for low-high-transitions the corresponding true local bit line lb_t is dipping down to a voltage value x smaller than a source voltage, which is shown in FIGS. 3 and 4. Since a pull-up NFET 22 in the local evaluation circuit 20 is not reliably suppressing the discharging of the true local bit line lb_t a false write through possibly propagates to the true global bit line gb_t through a NAND-Gate, combining the true local bit line lb_t of the upper part and the true local bit line lb_t of the lower part of FIG. 2, to a circuit node dt and a pull-down NFET 24, wherein signals at circuit node dt in the true read path and the corresponding node dc in the complementary read path are shown in FIGS. 3 and 4. So the true global bit line gb_t, which should show a logical high level due to the true dynamic write data w_data_t, shown in FIGS. 3 and 4, changing from the logic low level to the logic high level, is discharged to a logic low level, shown in FIGS. 3 and 4. This discharge will be impossible to recover from until the next cycle, thereby resulting in an incorrect value being read on the true global bit line gb_t by the read head circuit 40 during die “write-through”. The read head circuit 40 inverts the signal of the true global bit line gb_t and transfers the inverted signal to the first circuit node A where the inverted signal would gate a corresponding NFET, so that the false write through data would be propagated to the following latch structure 70, if the circuit arrangement for performing a write through operation according to the invention would not be in use.

Still referring to FIG. 2 the false write through preventing means 60 comprises a logical gate to logically link the information about the input data data, data_b to be written in the SRAM cell 10, which is in the shown embodiment represented by the dynamic data w_data_t, with a true global clock signal grst_t to generate the corresponding false write through preventing signal fwtp_t which controls a pull-up transistor 52 in a corresponding connecting structure 50 to retain the corresponding first output node C and therefore a corresponding output signal gb_t_xnand at the logical high level, shown in FIGS. 3 and 4. The false write through preventing signal fwtp_t is also controlling a pull-down transistor 62 in the false write through preventing means 60 to prevent switching of the corresponding circuit node C to the logical low level, wherein the false write through preventing signal fwtp_t is blocking the pull-down transistor 62. So the false write through data are blocked in the connecting structure 50, because the first output node C of the SRAM array 1 is retained at a high level in case of a low-high-transition at the first node t of the SRAM cell 10 based on the information about the input data data, data_b to be written in the SRAM cell 10 represented by the true dynamic write data w_data_t.

The operation of the system in case of a low-high-transition at the second node d of the SRAM cell 10 in the upper part of FIG. 2 during a write operation is analogous except that the complementary local bit line lb_c and complementary global bit line gb_c are concerned and the second false write through preventing means 60 on the left side of FIG. 2 is used to generate the false write through preventing signal fwtp_c based on the complementary dynamic write data w_data_c and a complementary global clock signal grst_c.

Finally a method for performing a write through operation during a write operation of a SRAM cell 10 of the SRAM array 1, comprises suppressing a false write through data propagation at an output of the SRAM array 1 in case of a low-high-transition at the first node t or the second node c of the corresponding SRAM cell 10 by using information about input data data, data_b to be written in the SRAM cell 10 and read data propagation paths to retain a corresponding output node C, F after a global bit line gb_t, gb_c at a logical high level independently from a logical level of the global bit line gb_t, gb_c, if a corresponding node c, t of the SRAM cell 10 is performing the low-high-transition based on input data data, data_b to be written in the SRAM cell 10. A first output node C of the SRAM array 1 after a true global bit line gb_t is retained at the logical high level, if a true node t of the SRAM cell 10 is performing the low-high-transition based on the input data data, data_b, or a second output node F of the SRAM array 1 after a complementary global bit line gb_c is retained at the logical high level, if a complementary node c of the SRAM cell 10 is performing the low-high-transition based on the input data data, data_b.

Embodiments of the present invention have been exemplary described with reference to a dynamic N-Domino structure using SRAM cells implemented with NFETs as passgates and PFETs to couple or decouple local bit line pairs to a voltage source. As will be appreciated by those skilled in the art, other structures like a dynamic P-Domino structure using SRAM cells implemented with PFETs as passgates and NFETs to couple or decouple local bit line pairs to a voltage source may also be used without departing from the main idea of the present invention.

Embodiment of the present invention address a false write through blocking circuitry for high performance/low power SRAM arrays using a dual bit line/dual word line approach and providing one write or two read port operation per cycle. The primary focus of this invention is to provide a circuitry for preventing false write through data from propagating to the array outputs during a write operation. In opposite to state of the art write bypass or write around schemes this invention uses the read data propagation paths to provide write through functionality in order to improve observability and testability of the circuit.

Embodiments of the present invention offer an area efficient false write through blocking circuitry for SRAM designs without global bit select functionality by write data controlled blocking of false write through data right after global bit lines and avoiding usage of state of the art write bypass/write around schemes.

What is claimed is:

1. A method for performing a write through operation during a write operation of a SRAM cell (10) of a SRAM array (1), comprising
suppressing a false write through data propagation at an output node (C, F) of said SRAM array (1) in case of a failure causing transition at a first node (t) or a second node (c) of said SRAM cell (10) by using information about said input data (data, data_b) to be written in said SRAM cell (10) and read data propagation paths to retain said circuit node (C, F) after a global bit line (gb_t, gb_c) at a precharge level independently from a logical level of said global bit line (gb_t, gb_c), if a corresponding node (c, t) of said SRAM cell (10) is performing said failure causing transition based on said input data (data, data_b) to be written in said SRAM cell (10).

2. The method according to claim 1, wherein said failure causing transition is a low-high-transition in case of a SRAM cell configured with NFETs as gating elements and said corresponding precharge level is a logical high level in case of a PFET used as precharge device, and wherein said failure causing transition is a high-low-transition in case of a SRAM cell configured with PFETs as gating elements and said corresponding precharge level is a logical low level in case of a NFET used as precharge device.

3. The method according to claim 1 or 2, wherein a first output node (C) of said SRAM array (1) after a true global bit line (gb_t) is forced to retain said precharge level, if a true node (t) of said SRAM cell (10) is performing said failure causing transition based on said input data (data, data_b), or a second output node (F) of said SRAM array (1) after a complementary global bit line (gb_c) is forced to retain said precharge level, if a complementary node (c) of said SRAM cell (10) is performing said failure causing transition based on said input data (data, data_b).

4. The method according to one of the preceding claims 1 to 3, wherein said input data (data, data_b) are gated by a dynamic write enable signal (wrt) to generate corresponding dynamic write data (w_data_t, w_data_c), wherein said input data (data, data_b) and/or said dynamic write data (w_data_t, w_data_c) are used to gain said information about said input data (data, data_b) to be written in said SRAM cell (10).

5. The method according to claim 4, wherein said information about said input data (data, data_b) to be written in said SRAM cell (10) is represented by a failure causing transition of said input data (data, data_b) and/or said dynamic write data (w_data_t, w_data_c).

6. The method according to claim 4 or 5, wherein said information about said input data (data, data_b) is gated by a global clock signal (grst_t, grst_c) to generate a corresponding false write through preventing signal (fwtp_t, fwtp_c).

7. The method according to claim 6, wherein said false write through preventing signal (fwtp_t, fwtp_c) is used to control a precharge device (52) to retain said corresponding output node (C, F) at said precharge level and to control an evaluation device (62) to prevent switching of said corresponding output node (C, F) to said evaluation level.

8. A circuit arrangement for performing a write through operation during a write operation of a SRAM cell (10) of a SRAM array (1),
comprising
false write through preventing means (60) suppressing a false write through data propagation at an output node (C, F) of a SRAM array (1) in case of a failure causing transition at a first node (t) or a second node (c) of said SRAM cell (10) by using information about input data (data, data_b) to be written in said SRAM cell (10) to generate a false write through preventing signal (fwtp_t, fwtp_c), which is used to retain said output node (C, F) of a read data propagation path at a precharge level after a global bit line (gb_t, gb_c) independently from a logical level of said global bit line (gb_t, gb_c), if a corresponding node (c, t) of said SRAM cell (10) is performing said failure causing transition based on input data (data, data_b) to be written in said SRAM cell (10).

9. The circuit arrangement according to claim 8, wherein said failure causing transition is a low-high-transition in case of a SRAM cell configured with NFETs as gating elements and said corresponding precharge level is a logical high level in case of a PFET used as precharge device, and wherein said failure causing transition is a high-low-transition in case of a SRAM cell configured with PFETs as gating elements and said corresponding precharge level is a logical low level in case of a NFET used as precharge device.

10. The circuit arrangement according to claim 8 or 9, wherein a write data gating logic (30) comprises at least one logical gate to gate said input data (data, data_b) by a dynamic write enable signal (wrt) to generate corresponding dynamic write data (w_data_t, w_data_c), wherein said input data (data, data_b) and/or said dynamic write data (w_data_t, w_data_c) are used to gain said information about said input data (data, data_b) to be written in said SRAM cell (10).

11. The circuit arrangement according to claim 8 or 9, wherein said information about input data (data, data_b) to be written in said SRAM cell (10) is represented by a failure causing transition of said input data (data, data_b) and/or said dynamic write data (w_data_t, w_data_c).

12. The circuit arrangement according to one of the preceding claims 8 to 11, wherein said false write through preventing means (60) comprises a logical gate to logically link said information about said input data (data, data_b) to be written in said SRAM cell (10) with a global clock signal (grst_t, grst_c) to generate said corresponding false write through preventing signal (fwtp_t, fwtp_c).

13. The circuit arrangement according to claim 10, wherein said false write through preventing signal (fwtp_t, fwtp_c) controls a precharge device (52) in a connecting structure (50) to retain said corresponding output node (C, F) at said precharge level and an evaluation device (62) in said false write through preventing means (60) to prevent switching of said corresponding circuit node (C, F) to said evaluation level.

14. A SRAM array with write through capability comprising
a plurality of SRAM cells (10) and corresponding local evaluation circuits (20) with local bit lines (lb_t, lb_c) and word lines (wl_c_n, wl_t_n, wl_c_(n+k), wl_t_(n+k)) for performing write and read operations, read head circuits (40) to read logical level of global bit lines (gb_t, gb_c), and
a connecting structure (50) to connect at least one SRAM subarray (1.1, 1.2) to a common output node (C, F), characterized in
a circuit arrangement according to one of the preceding claims 8 to 13 for performing a write through operation during a write operation of a SRAM cell (10) of said SRAM array (1).

15. The SRAM array according to claim 14, wherein a dual bit line/dual word line approach is used and one write or two read port operations are performed per cycle.
